(19) United States
(12) Patent Application Publication
(10) Pub. No.: US 2025/0081697 A1
(43) Pub. Date: Mar. 6, 2025

(54) DISPLAY PANEL, METHOD FOR MANUFACTURING DISPLAY PANEL, AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Yuting FU, Hefei (CN); Yi-Yu LAI, Hefei (CN); Liusong NI, Hefei (CN); Yanlong HU, Hefei (CN); Ruyi AN, Hefei (CN); Lipeng GAO, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/758,375

(22) Filed: Jun. 28, 2024

(30) Foreign Application Priority Data
Aug. 31, 2023 (CN) 202311124845.7

(51) Int. Cl. H01L 33/62; H01L 25/075; H01L 25/16

(52) U.S. Cl. CPC H10H 20/857; H01L 25/0753; H01L 25/167; H10H 20/0364

(57) ABSTRACT

A display panel, a method for manufacturing a display panel, and a display apparatus. The display panel includes a display region, a non-display region at least partially surrounding the display region, and further includes a base plate, a wiring layer, a light-emitting layer, and an isolation structure. The wiring layer is located on a side of the base plate and includes a metal layer located in the display region and a signal line layer located in the non-display region. The light-emitting layer is located on a side of the wiring layer away from the base plate and includes a plurality of light-emitting units. The isolation structure is located on a side of the wiring layer away from the base plate and is provided with an isolation opening configured to accommodate the light-emitting unit.

### CROSS REFERENCE TO RELATED APPLICATION

The present application claims priority to Chinese Patent Application No. 202311124845.7 filed on Aug. 31, 2023, and titled “DISPLAY PANEL, METHOD FOR MANUFACTURING DISPLAY PANEL, AND DISPLAY APPARATUS”, which is incorporated herein by reference in its entirety.

### TECHNICAL FIELD

The present application relates to the field of display technology, and in particular, to a display panel, a method for manufacturing a display panel, and a display apparatus.

### BACKGROUND

A flat display panel such as an organic light emitting display (OLED) panel and a display panel using a light emitting diode (LED) device is widely used in various consumer electronic products such as mobile phones, TVs, personal digital assistants, digital cameras, notebook computers, and desktop computers due to advantages such as high image quality, power saving, a thin body and a wide application range, becoming the mainstream in display devices.

However, some current organic light emitting display panels still have a problem of poor signal.

### SUMMARY

Embodiments of the present application provide a display panel, a method for manufacturing a display panel, and a display apparatus, which can reduce the possibility of damage to a signal line in a non-display region.

In a first aspect, the embodiments of the present application provide a display panel including a display region and a non-display region at least partially surrounding the display region, and the display panel includes a base plate, a wiring layer, a light-emitting layer, and an isolation structure. The wiring layer is located on a side of the base plate, and includes a metal layer located in the display region and a signal line layer located in the non-display region. The isolation structure is located on a side of the wiring layer away from the base plate and is provided with an isolation opening configured to accommodate the light-emitting unit. The isolation structure is electrically connected to the signal line layer, and at least a part of a side of the signal line layer away from the base plate is provided with a protection portion.

In a second aspect, the embodiments of the present application provide a method for manufacturing a display panel, and the method includes the following steps: forming a wiring layer on a side of a base plate, wherein the wiring layer includes a metal layer located in a display region and a signal line layer located in a non-display region; forming a protection material layer on a side of the signal line layer away from the base plate, and performing a patterning treatment on the protection material layer to form a protection portion located on the side of the signal line layer away from the base plate; forming an isolation structure on a side of the wiring layer away from the base plate, wherein the isolation structure is provided with an isolation opening configured to accommodate a light-emitting unit.

In a third aspect, the embodiments of the present application provide a display apparatus including a display panel as described above.

The embodiments of the present application provide the display panel, the method for manufacturing the display panel, and the display apparatus. In the manufacturing process of the display panel, the signal line layer may be manufactured before the isolation structure, and the protection portion may be manufactured on a side of the signal line layer away from the base plate before the isolation structure or a subsequent film layer of the signal line layer is manufactured, so as to reduce the possibility of causing damage to the signal line layer due to the erosion of the signal line layer in the manufacturing process of the isolation structure or other subsequent film layers, thereby improving the reliability of the display panel.

### BRIEF DESCRIPTION OF THE DRAWINGS

Other features, objects and advantages of the present application will become more apparent from reading the following detailed description of the non-limiting embodiments with reference to the accompanying drawings, in which the same or similar reference numbers represent the same or similar features.

FIG. 1 is a schematic structural view of a display panel according to embodiments of the present application;

FIG. 2 is a schematic view of a relative positional relationship between the isolation structure and the first signal line at the region Q in FIG. 1;

FIG. 3 is a cross-sectional schematic structural view at A-A in FIG. 2;

FIG. 4 is a cross-sectional schematic structural view of another display panel at A-A according to embodiments of the present application;

FIG. 5 is a cross-sectional schematic structural view of another display panel at A-A according to embodiments of the present application;

FIG. 6 is a cross-sectional schematic structural view of a display panel according to embodiments of the present application;

FIG. 7 is a cross-sectional schematic structural view of another display panel at A-A according to embodiments of the present application;

FIG. 8 is a cross-sectional schematic structural view of another display panel at A-A according to embodiments of the present application;

FIG. 9 is a cross-sectional schematic structural view of another display panel at A-A according to embodiments of the present application;

FIG. 10 is a flowchart of a method for manufacturing a display panel according to embodiments of the present application;

FIG. 10A to FIG. 10C are schematic views of a manufacturing process of a method for manufacturing a display panel according to embodiments of the present application;

FIG. 11A to FIG. 11B are schematic views of a manufacturing process of a method for manufacturing another display panel according to embodiments of the present application.

### REFERENCE NUMBERS

10: Base plate; 11: Driving circuit; 12: Planarization layer;
20: Isolation structure; 21: Isolation opening; 22: First isolation portion; 23: Second isolation portion; 24: Third isolation portion;
30: Light-emitting unit;
40: Wiring layer; 41: Signal line layer; 411: First surface; 412: Second surface; 42: Conductive connection portion; 43: Signal line connection portion;
50: Protection portion; 51: First sub-layer; 52: Second sub-layer;
60: First electrode;
70: Second electrode;
80: Pixel definition layer; 81: Pixel definition portion; 811: Accommodation groove;
82: Pixel opening; 90: Conductive portion;
D1: Protection material layer; D2: Pixel definition material layer; IC: Driving chip;
AA: Display region; NA: Non-display region;
X: First direction; Y: Thickness direction.

In the accompanying drawings, the same reference numbers are used for the same components. The accompanying drawings are not drawn to actual scale.

### DETAILED DESCRIPTION

In the related art, various circuit structures generally need to be provided around the frame of the display panel to satisfy the normal operation need of the display panel. After these circuit structures are manufactured, other structures are generally manufactured in the display region. During the manufacturing of other structures, the circuit structures may be eroded, thereby causing damage to the circuit structures, and resulting in problems such as a reduced signal transmission effect or even signal transmission failure.

Accordingly, in order to solve the above problems, in a first aspect, the embodiments of the present application provide a display panel, a method for manufacturing a display panel, and a display apparatus.

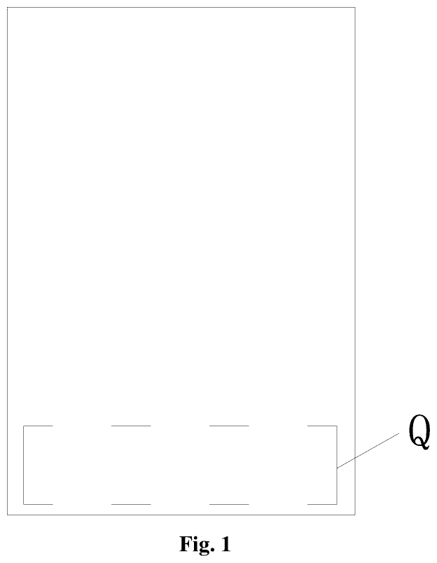

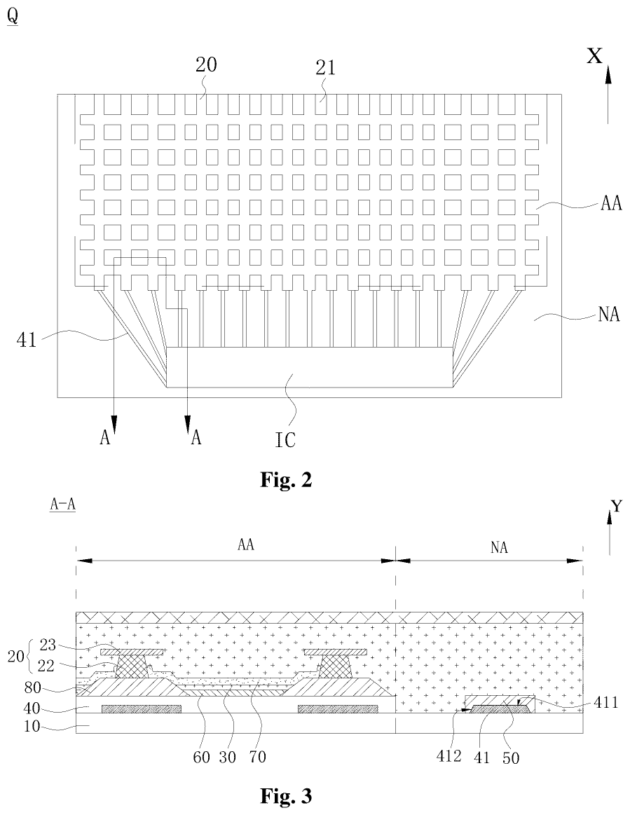

FIG. 1 is a schematic structural view of a display panel according to embodiments of the present application. FIG. 2 is a schematic view of a relative positional relationship between the isolation structure and the first signal line at the region Q in FIG. 1. FIG. 3 is a cross-sectional schematic structural view at A-A in FIG. 2.

As shown in FIG. 1 to FIG. 3, the present application provides a display panel including a display region AA and a non-display region NA at least partially surrounding the display region AA, and the display panel includes a base plate 10, a wiring layer 40, a light-emitting layer, and an isolation structure 20. The wiring layer 40 is located on a side of the base plate 10, and includes a metal layer located in the display region AA and a signal line layer 41 located in the non-display region NA. The isolation structure 20 is located on a side of the wiring layer 40 away from the base plate 10 and is provided with an isolation opening 21 configured to accommodate the light-emitting unit 30. The isolation structure 20 is electrically connected to the signal line layer 41, and at least a part of a side of the signal line layer 41 away from the base plate 10 is provided with a protection portion 50.

The display panel has at least two regions, the display region AA and the non-display region NA, the display region AA is a main region configured to achieve a display effect in the display panel, and the non-display region NA surrounds an outer circumference of the display region AA and is mainly used for arranging of signal lines in the display panel. Sizes and shapes of the display region AA and the non-display region NA are not limited in the embodiments of the present application. In an example, the display region AA may be a rectangular structure, the non-display region NA is provided on at least one side of the display region AA along a circumferential direction, and the non-display region NA may be a ring structure, a semi-ring structure, or a bar structure.

The base plate 10 mainly plays a supporting and bearing role, other film layers are stacked in sequence on the base plate 10, and the “stacked” mentioned herein means that other film layers are provided in sequence along a thickness direction Y of the base plate 10. The base plate 10 may include a plurality of film layers, and specific film layers of the base plate 10 are not limited in the embodiments of the present application. In addition, a thickness direction Y of other film layers located on a side of the base plate 10 is generally the same as the thickness direction Y of the base plate 10, and thus, for the convenience of description, the thickness direction Y of the base plate 10 or the thickness direction Y of other film layers mentioned subsequently in the embodiments of the present application is shown as the same direction.

The isolation structure 20 is located on the side of the wiring layer 40 away from the base plate 10, and encloses and forms the isolation opening 21 configured to accommodate the light-emitting unit 30, and the light-emitting unit 30 is one of main devices configured to emit light and display. The light-emitting unit 30 includes, but is not limited to, a red light-emitting unit configured to emit red light, a blue light-emitting unit configured to emit blue light, and a green light-emitting unit configured to emit green light. Each of light-emitting units 30 may include a hole inject layer (HIL), a hole transport layer (HTL), a light-emitting layer, an electron inject layer (EIL), and an electron transport layer (ETL) that are stacked.

The isolation opening 21 enclosed and formed by the isolation structure 20 can accommodate the light-emitting unit 30, in other words, an orthographic projection of the light-emitting unit 30 on the base plate 10 at least partially overlaps an orthographic projection of the isolation opening 21 on the base plate 10, and the orthographic projection of the light-emitting unit 30 on the base plate 10 is at least partially located within the orthographic projection of the isolation opening 21 on the base plate 10. Further, in the manufacturing process of the light-emitting unit 30, due to the presence of the isolation structure 20, a light-emitting material may be separated into the light-emitting units 30 independent from each other by the isolation structure 20, so that the fine metal mask evaporation process may be omitted.

For example, in an example where the red light-emitting unit is manufactured before the green light-emitting unit, since the fine metal mask is omitted, a red light-emitting material corresponding to the red light-emitting unit first falls into a corresponding isolation opening 21, then a selective etching is performed to remove the red light-emitting material in a part of the isolation openings 21, and the red light-emitting material in the other part of the isolation openings 21 remains, so that red light-emitting units are formed. After this, a green light-emitting material corresponding to a green light-emitting unit 30 falls into a corresponding isolation opening 21, then the selective etching is performed to remove the green light-emitting material in a part of the isolation openings 21, and the green light-emitting material in the other part of the isolation openings 21 remains, so that green light-emitting units are formed.

Further, the display panel may include a second electrode 70, the second electrode 70 and the first electrode 60 are respectively provided on two sides of the light-emitting unit, the second electrode 70 may be electrically connected to the isolation structure 20. That is, the isolation structure 20 may include a conductive material, and the second electrode 70 and the conductive material in the isolation structure 20 can be connected to each other, so that second electrodes in different isolation openings are interconnected through the isolation structure as a surface electrode. Optionally, the second electrode 70 may be a cathode.

The conductive material in the isolation structure 20 electrically connected to the second electrode 70 may be in a grid-like shape in the display region, so that second electrodes 70 in the display region may be interconnected through the isolation structure 20 as the surface electrode. Alternatively, the conductive material in the isolation structure 20 electrically connected to the second electrode 70 may be separated into a plurality of conductive portions independent from each other. That is, at least some of different second electrodes 70 may receive or transmit power supply signals of different voltage magnitudes through the isolation structure 20, thereby achieving independent or partitioned control over the light-emitting units 30, which is not limited in the embodiments of the present application.

The wiring layer 40 is provided on a side of the base plate 10 and includes a signal line layer 41 located in the non-display region NA, that is, the signal line layer 41 is insulated from other conductive film layers in the base plate 10 by an insulation layer. Optionally, the non-display region NA of the display panel is provided with a driving chip IC, and the signal line layer 41 is located between the driving chip IC and the display region AA. Optionally, a material of the signal line layer 41 includes a conductive material, and in an example, the material of the signal line layer 41 includes a metal material.

The signal line layer 41 may be configured to transmit a corresponding power supply signal to the second electrode 70. In the related art, the second electrodes 70 are provided on the whole surface of the display region, the signal line layer 41 electrically connected to respective second electrodes 70 is generally located in the non-display region NA and i provided around an outer circumference of the second electrodes 70 in a ring structure. This arrangement makes the first electrodes 60 occupy too much space in the frame of the display panel, which is not beneficial for achieving a narrow frame.

However, in the embodiments of the present application, the signal line layer 41 is not directly connected to the second electrode 70, but transmits the power supply signal to a corresponding second electrode 70 through the isolation structure 20. Specifically, since the isolation structure 20 is disposed corresponding to the second electrodes 70, signal transmission can be achieved between the isolation structure 20 and the second electrodes 70. Accordingly, the signal line layer 41 does not need to be extended to the second electrodes 70, that is, the signal line layer 41 does not need to be provided around the second electrodes 70, and the signal line layer 41 may be provided on one side of the isolation structure 20 along a first direction X and may be electrically connected to the isolation structure 20. In this way, the power supply signal in the signal line layer 41 can be transmitted to the second electrodes 70 through the isolation structure 20, thereby satisfying the signal transmission need. Since the signal line layer 41 is located on only one side of the isolation structure 20 along the first direction X and is not in a ring structure, it is helpful to reduce the size of the frame of the display panel and improve the display effect. Optionally, the first direction X intersects the thickness direction Y.

It should be noted that the specific wiring pattern of the signal line layer 41 is not limited in the embodiments of the present application. Depending on actual situations, the signal line layer 41 may be completely located on one side of the isolation structure 20 along the first direction X, or a small part of the signal line layer 41 may be located on other sides of the isolation structure 20 along different directions, as long as most of the signal line layer 41 is located on the same side of the isolation structure 20.

In the manufacturing process of the display panel according to the embodiments of the present application, the signal line layer 41 may be manufactured before the isolation structure 20, and the protection portion 50 may be manufactured on a side of the signal line layer 41 away from the base plate 10 before the isolation structure 20 or a subsequent film layer of the signal line layer 41 is manufactured, so as to reduce the possibility of causing damage to the signal line layer 41 due to the erosion of the signal line layer 41 in the manufacturing process of the isolation structure 20 or other subsequent film layers, thereby improving the reliability of the display panel.

In some embodiments, as shown in FIG. 3, the signal line layer 41 includes a first surface 411 located on a side of the signal line layer 41 away from the base plate 10 and a second surface 412 connected to two sides of the first surface 411 and extending toward the base plate 10, and the protection portion 50 covers the first surface 411 and the second surface 412.

The specific size and the shape of the signal line layer 41 are not limited in the embodiments of the present application. In an example, the cross section of the signal line layer 41 may be a rectangular shape or a trapezoidal shape, so that the resistance of the signal line layer 41 is reduced. An example is given in which the shape of the cross section of the signal line layer 41 is a trapezoid, the first surface 411 and the second surface 412 of the signal line layer 41 may be an upper base of the trapezoid and a waist of the trapezoid.

In the embodiments of the present application, the protection portion 50 covers the first surface 411 and the second surface 412, so that the possibility of causing erosion to the signal line layer 41 by the isolation structure 20 or other film layers in the manufacturing process is further reduced, and the possibility of causing damage to the signal line layer 41 is reduced.

In some embodiments, the signal line layer 41 and the metal layer are provided on a same layer, and at least some of materials of the signal line layer 41 and the metal layer are the same, so that the signal line layer 41 and the metal layer are manufactured in the same process step.

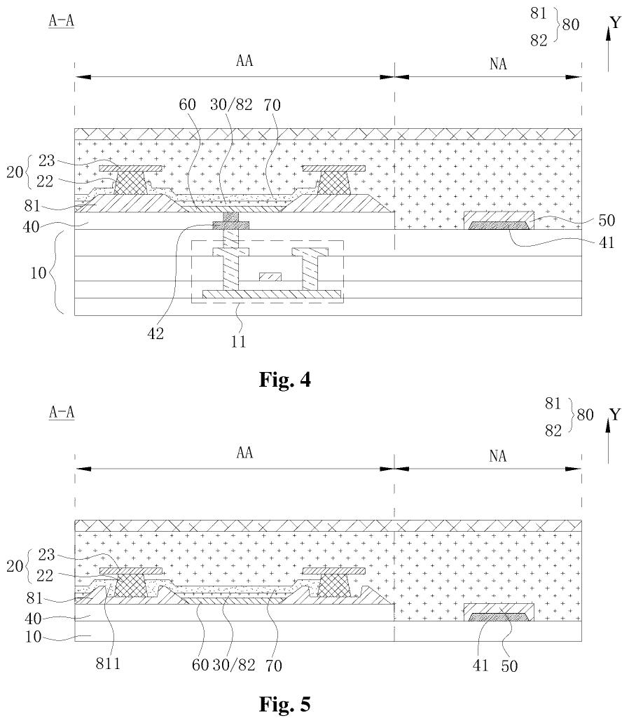

FIG. 4 is a cross-sectional schematic structural view of another display panel at A-A according to embodiments of the present application.

In some embodiments, as shown in FIG. 4, the wiring layer 40 further includes a conductive connection portion 42 located in the display region AA, the base plate 10 includes a driving circuit 11, the display panel further includes a first electrode 60 located between the light-emitting layer and the base plate, the first electrode 60 is located on a side of the conductive connection portion 42 away from the driving circuit 11, and the first electrode 60 and the driving circuit 11 are connected through the conductive connection portion 42.

Optionally, the first electrode 60 and the second electrode 70 are respectively provided on two opposite sides of the light-emitting unit 30 along the thickness direction Y, the display panel may include a plurality of first electrodes 60, the first electrode 60 corresponds to the light-emitting unit 30, and the first electrode 60 and the second electrode 70 together drive and control the light-emitting unit 30 to emit light. In an example, the first electrode 60 is an anode, and the second electrode 70 is a cathode. A plurality of insulation layers may be provided between the first electrode 60 and the driving circuit 11, a via is provided in the insulation layer, and the conductive connection portion 42 is connected to the first electrode 60 and the driving circuit 11 through the via.

Optionally, a material of the conductive connection portion 42 is the same as a material of the signal line layer 41. In an example, the conductive connection portion 42 and the signal line layer 41 are manufactured in the same process step.

Further, the signal line layer 41 may be completely located in the non-display region NA, or a part of the signal line layer 41 may extend into the display region AA. Similarly, the isolation structure 20 may be completely located in the display region AA, or a part of the isolation structure 20 may extend into the non-display region NA. Similarly, the conductive connection portion 42 may be completely located in the display region AA, or a part of the conductive connection portion 42 may extend into the non-display region NA.

In some embodiments, as shown in FIG. 3 and FIG. 4, the display panel further includes a pixel definition layer 80 provided on the base plate 10, the pixel definition layer 80 includes a pixel definition portion 81 and a pixel opening 82 defined by the pixel definition portion 81, the pixel opening 82 and the isolation opening 21 are connected to accommodate the light-emitting unit 30, an orthographic projection of each of the pixel openings 82 on the base plate 10 is located within an orthographic projection of a corresponding isolation opening 21 on the base plate 10, and at least a part of the protection portion 50 and the pixel definition portion 81 are made of a same material.

The pixel definition layer 80 includes the pixel definition portion 81 and the pixel opening 82, the pixel opening 82 corresponds to the isolation opening 21, in an example, the orthographic projection of the pixel opening 82 on the base plate 10 may be located within the orthographic projection of the isolation opening 21 on the base plate 10, and some structures in the light-emitting unit 30 and the second electrode 70 may be located within the pixel opening 82.

In some examples, at least a part of the protection portion 50 and the pixel definition portion 81 are made of the same material, that is, the protection portion 50 and the pixel definition portion 81 may be manufactured in the same process step.

It may be known from the foregoing that the signal line layer 41 and the conductive connection portion 42 may be manufactured in the same process step, and thus a distance between the signal line layer 41 and the substrate in the base plate 10 may be the same as a distance between the conductive connection portion 42 and the substrate in the base plate 10, so that a distance between the protection portion 50 and the substrate may be less than or equal to a distance between the pixel definition portion 81 and the substrate, thereby reducing an effect of the protection portion 50 on a thickness of film layers in the non-display region NA, and further reducing an overall thickness of the film layers in the non-display region NA.

FIG. 5 is a cross-sectional schematic structural view of another display panel at A-A according to embodiments of the present application.

In some embodiments, as shown in FIG. 4 and FIG. 5, the isolation structure 20 is provided on a side of the pixel definition portion 81 away from the base plate 10, or the pixel definition portion 81 is provided with an accommodation groove 811, and the isolation structure 20 is provided in the accommodation groove 811.

The isolation structure 20 is provided on the side of the pixel definition portion 81 away from the base plate 10, that is, an orthographic projection of the isolation structure 20 on the base plate 10 falls within an orthographic projection of the pixel definition portion 81 on the base plate 10, so as to improve a partitioning effect of the isolation opening 21 enclosed and formed by the isolation structure 20.

The pixel definition portion 81 is provided with the accommodation groove 811, and the accommodation groove 811 may be formed by recessing a side of the pixel definition portion 81 away from the base plate 10. Optionally, a recess depth of the accommodation groove 811 and a recess depth of the pixel opening 82 may be the same or different. Optionally, the accommodation groove 811 may penetrate through the pixel definition portion 81.

Optionally, one or more accommodation grooves 811 may be provided between two adjacent pixel openings 82. The isolation structure 20 is provided in the accommodation groove 811, so that a space occupied by the isolation structure 20 along the thickness direction Y of the display panel can be reduced, thereby reducing an overall thickness of the display panel.

In some embodiments, a material of the protection portion 50 includes an inorganic material, so that the protection portion 50 has a desired hermetic sealing, and thus the possibility is reduced that the protection portion 50 will be eroded under a condition that the protection portion 50 is in contact with the etching solution or etching gas for the isolation structure 20 or other film layers, thereby reducing the possibility of failure of the signal line layer 41 due to erosion of the signal line layer 41 caused by the protection portion 50 exposing at least a part of the signal line layer 41.

FIG. 6 is a cross-sectional schematic structural view of a display panel according to embodiments of the present application.

In some embodiments, as shown in FIG. 6, the pixel definition portion 81 is provided with a via 43, and the signal line layer 41 is electrically connected to the isolation structure 20 through the via 43.

Optionally, a part of the signal line layer 41 may extend to the display region AA, and the via penetrates through the pixel definition portion 81 along the thickness direction of the display panel.

In some other examples, a part of the isolation structure 20 is located in the non-display region NA, and the via may be provided on the protection portion 50. Specifically, after the isolation structure 20 is manufactured, the via 43 is formed on the protection portion 50, and a part of the isolation structure 20 located in the non-display region NA may be electrically connected to the signal line layer 41 through the via 43.

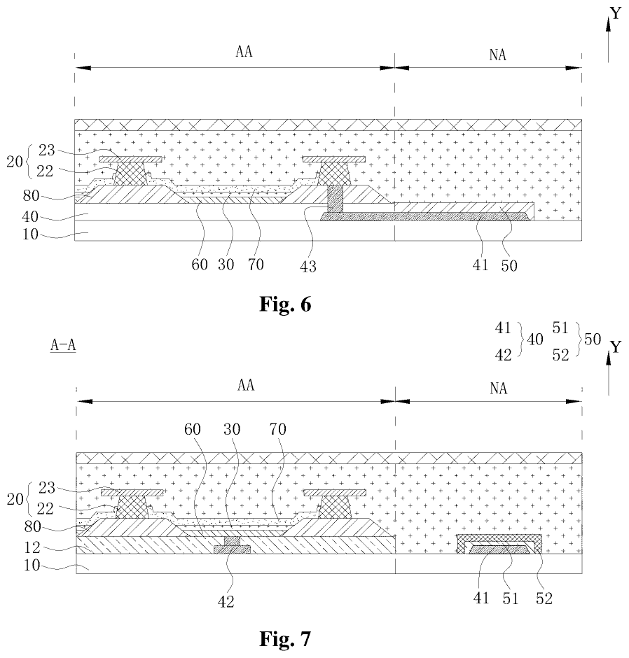

FIG. 7 is a cross-sectional schematic structural view of another display panel at A-A according to embodiments of the present application.

In some embodiments, as shown in FIG. 7, the base plate 10 further includes a planarization layer 12, and the protection portion 50 includes a first sub-layer 51 and a second sub-layer 52 stacked along a thickness direction Y of the base plate 10, the first sub-layer 51 and the planarization layer 12 are made of a same material, and the second sub-layer 52 and the pixel definition portion 81 are made of a same material.

Optionally, the first sub-layer 51 and the second sub-layer 52 of the protection portion 50 may cover the same region of the signal line layer 41, in an example, the first sub-layer 51 covers the first surface 411 and the second surface 412 of the signal line layer 41, and the second sub-layer 52 covers a region of the first sub-layer 51 corresponding to the first surface 411 and the second surface 412 of the signal line layer 41. Of course, the first sub-layer 51 and the second sub-layer 52 of the protection portion 50 may cover different regions of the signal line layer 41, in an example, the first sub-layer 51 covers the first surface 411 of the signal line layer 41, and the second sub-layer 52 covers the second surface 412 of the signal line layer 41 and a region of the first sub-layer 51 corresponding to the first surface 411 of the signal line layer 41.

The first sub-layer 51 and the planarization layer 12 are made of a same material, that is, the first sub-layer 51 and the planarization layer 12 may be manufactured in the same process step. The second sub-layer 52 and the pixel definition portion 81 are made of a same material, that is, the second sub-layer 52 and the pixel definition portion 81 may be manufactured in the same process step. Therefore, the possibility that the first sub-layer 51 reacts with other substances after the second sub-layer 52 reacts with other substances is reduced, thereby improving the reliability of the protection portion 50.

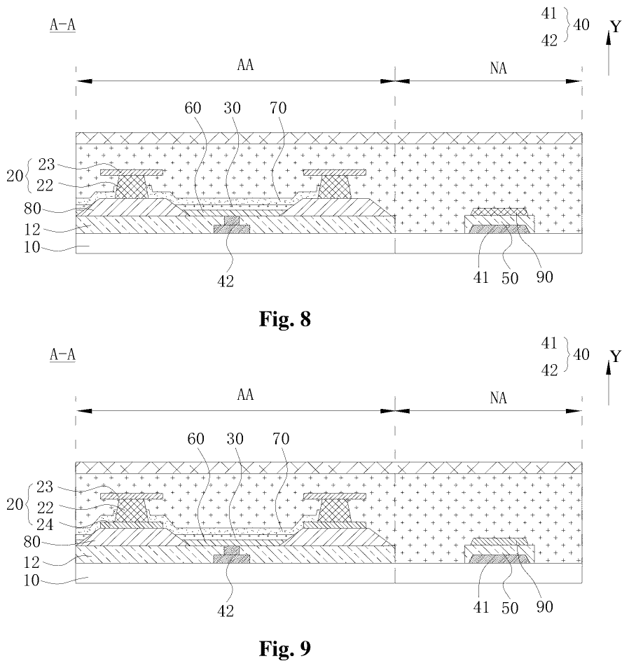

FIG. 8 is a cross-sectional schematic structural view of another display panel at A-A according to embodiments of the present application.

In some embodiments, as shown in FIG. 8, the isolation structure 20 includes a first isolation portion 22 and a second isolation portion 23 located on a side of the first isolation portion 22 away from the base plate 10, an orthographic projection of the first isolation portion 22 on the base plate 10 is located within an orthographic projection of the second isolation portion 23 on the base plate 10. The display panel further includes a conductive portion 90 located in the non-display region NA, the conductive portion 90 is located on a side of the protection portion 50 away from the signal line layer 41, and the conductive portion 90 and the first isolation portion 22 are made of a same material.

Specific sizes and shapes of the first isolation portion 22 and the second isolation portion 23 are not limited in the embodiments of the present application. In an example, a longitudinal cross-section of the isolation structure 20 may be T-shaped. In the manufacturing process of the light-emitting unit 30 and the second electrode 70, such design helps to make it difficult for the light-emitting material and the electrode material to extend along a side wall of the first isolation region 22 to a side wall of the second spacer 23, thereby achieving manufacturing and separation of the light-emitting units 30 and the second electrodes 70 in different isolation openings 21 under a condition that the fine metal mask is not required.

Materials of the first isolation portion 22 and the second isolation portion 23 are not limited in the embodiments of the present application. The first isolation portion 22 and the second isolation portion 23 both may include a conductive material, or the first isolation portion 22 includes a conductive material while the second isolation portion 23 includes an insulation material, as long as the first electrode can achieve signal transmission through the isolation structure 20.

The conductive portion 90 may be configured to connect a functional film layer in the display region AA to the driving chip IC, so that a signal in the driving chip IC can be transmitted to the functional film layer. The conductive portion 90 and the first isolation portion 22 are made of a same material, that is, the conductive portion 90 and the first isolation portion 22 may be manufactured in the same process step, so that the conductive portion 90 and the first isolation portion 22 may be manufactured simultaneously in the manufacturing process, thereby reducing the manufacturing cost.

In some embodiments, the material of the conductive portion 90 includes molybdenum or aluminum, so that the conductivity of the conductive portion 90 is improved.

FIG. 9 is a cross-sectional schematic structural view of another display panel at A-A according to embodiments of the present application.

In some embodiments, as shown in FIG. 9, the isolation structure 20 further includes a third isolation portion 24, the first isolation portion 22 is located between the third isolation portion 24 and the second isolation portion 23, and the conductive portion 90 and the third isolation portion 24 are made of a same material.

The insulation structure 20 at least includes the first insulation portion 22, the second insulation portion 23, and the third insulation portion 24, and sizes and shapes of the first insulation portion 22, the second insulation portion 23, and the third insulation portion 24 are not limited in the embodiments of the present application. In an example, the orthographic projection of the first isolation portion 22 on the base plate 10 is positioned within an orthographic projection of the third isolation portion 24 on the base plate 10, that is, the longitudinal cross-section of the first isolation portion 22, the second isolation portion 23 and the third isolation portion 24 is I-shaped.

Similar to the first isolation portion 22, the third isolation portion 24 also includes the conductive material, and the second electrode 70 may be in direct contact with the third isolation portion 24, so that the first electrode 41 is electrically connected to the first isolation portion 22 through the third isolation portion 24. Optionally, the second electrode 70 is overlapped with the third isolation portion 24. Further, the second electrode 70 may be partially positioned on a side of the third isolation portion 24 away from the base plate 10, and providing the third isolation portion 24 is helpful to improve the reliability of the electrical connection between the second electrode 70 and the isolation structure 20.

The conductive portion 90 and the third isolation portion 24 are made of the same material, that is, the conductive portion 90 and the third isolation portion 24 may be made of the same material. It may be known from the foregoing that the conductive portion 90 and the third isolation portion 24 may be made of the same material, and the conductive portion 90 may include a first sub-portion and a second sub-portion stacked along the thickness direction Y of the base plate 10, the first sub-portion and the third isolation portion 24 are made of a same material, and the second sub-portion and the first isolation portion 22 are made of a same material, thereby further reducing the resistance of the conductive portion 90 and improving the reliability of the conductive portion 90.

In some examples, the conductive portion 90 and only the first isolation portion 22 may be made of a same material. In some other examples, the conductive portion 90 and only the third isolation portion 24 may be made of a same material.

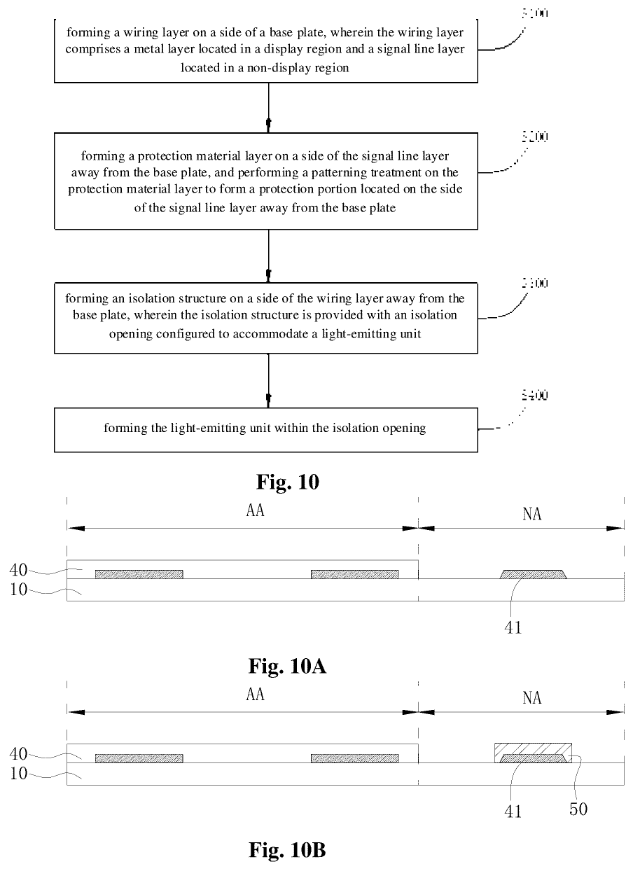

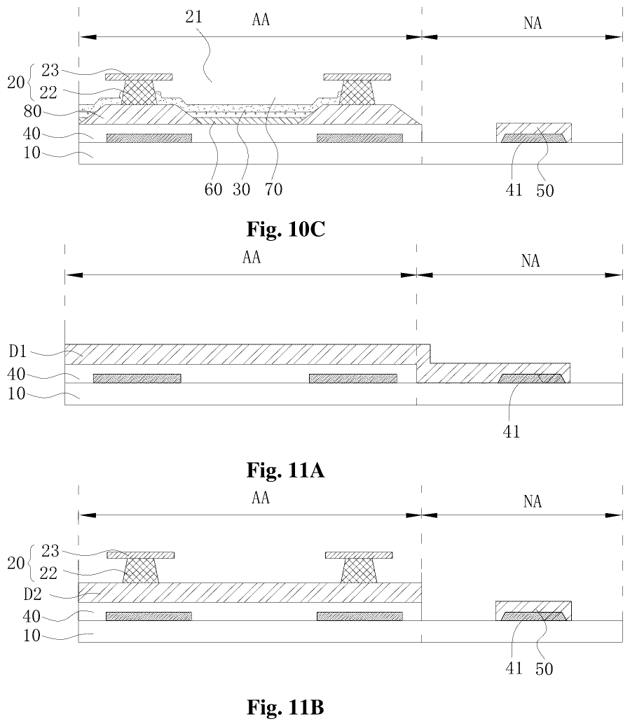

FIG. 10 is a flowchart of a method for manufacturing a display panel according to embodiments of the present application. FIG. 10A to FIG. 10C are schematic views of a manufacturing process of a method for manufacturing a display panel according to embodiments of the present application. FIG. 11A to FIG. 11B are schematic views of a manufacturing process of a method for manufacturing another display panel according to embodiments of the present application.

In a second aspect, as shown in FIG. 10, the present application provides a method for manufacturing a display panel which may be the display panel according to FIG. 1 to FIG. 9, and the method for manufacturing the display panel includes S100 to S400.

S100, forming a wiring layer 40 on a side of a base plate 10, wherein the wiring layer 40 includes a metal layer located in a display region AA and a signal line layer 41 located in a non-display region NA.

In some embodiments, as shown in FIG. 10A, in step S100, the wiring layer 40 is formed on a side of the base plate 10, that is, a conductive material layer is provided on a side of the base plate 10, and a patterning treatment is performed on the conductive material layer to form the signal line layer 41 and the metal layer. Optionally, a material of the signal line layer 41 includes a three-layer metal structure of titanium-aluminum-titanium.

S200, forming a protection material layer D1 on a side of the signal line layer 41 away from the base plate 10, and performing the patterning treatment on the protection material layer D1 to form a protection portion 50 located on the side of the signal line layer 41 away from the base plate 10.

In some embodiments, as shown in FIG. 10B, in step S200, after the protection material layer D1 is patterned, only the protection portion 50 may be formed, or other film layers in the display region AA may be formed while the protection portion 50 is formed. Optionally, the protection material layer D1 may be manufactured by a process such as photolithography.

S300, forming an isolation structure 20 on a side of the wiring layer 40 away from the base plate 10, wherein the isolation structure 20 is provided with an isolation opening 21 configured to accommodate a light-emitting unit 30.

In some embodiments, as shown in FIG. 10C, in step S300, in the manufacturing process of the isolation structure 20, in order to facilitate the manufacturing of the first isolation portion 22 and the second isolation portion 23, the first isolation portion 22 is manufactured by wet etching, etching solution used in the manufacturing process of the first isolation structure 22 may cause erosion to the metal material, and in order to reduce the possibility of the etching solution eroding the signal line layer 41, the protection portion 50 may cover the surface of the signal line layer 41.

S400, forming the light-emitting unit within the isolation opening.

In some embodiments, as shown in FIG. 10C, in step S400, light-emitting units 30 of different colors are formed in isolation openings 21. In an example, a red light-emitting unit, a green light-emitting unit, and a blue light-emitting unit are respectively formed in the plurality of isolation openings 21. In the forming process of the light-emitting units 30, the fine metal mask may be replaced with the isolation structure.

In some embodiments, as shown in FIG. 10C, FIG. 11A, and FIG. 11B, step S200 includes:

S210, performing the patterning treatment on the protection material layer D1 further forms a pixel definition portion 81 and a pixel opening 82, the pixel opening 82 and the isolation opening 21 are connected to accommodate the light-emitting unit 30, an orthographic projection of an inner wall of each of pixel openings 82 on the base plate 10 is located within an orthographic projection of an inner wall of each of a corresponding isolation opening 21 on the base plate 10, and at least a part of the protection portion 50 and the pixel definition portion 81 are made of a same material.

In some embodiments, in step S210, the manufacturing of the pixel definition portion 81 and the pixel opening 82 may be before the manufacturing of the isolation structure 20, or the manufacturing of the pixel definition portion 81 and the pixel opening 82 may be after the manufacturing of the isolation structure 20. In the embodiments of the present application, an example is given in which the manufacturing of the pixel definition portion 81 and the pixel opening 82 may be after the manufacturing of the isolation structure 20. As shown in FIG. 11A, the protection material layer D1 may cover the display region AA and the non-display region NA; as shown in FIG. 11B, the patterning treatment is performed on the protection material layer D1 to form the pixel definition material layer D2 and the protection portion, and form the isolation structure 20 in a corresponding region of the pixel definition material layer D2, then form the pixel definition portion 81 and the pixel opening 82, so that the possibility is reduced that the isolation structure 20 causes damage to the signal line layer 41 and the first electrode 60 in the manufacturing process.

In a third aspect, the embodiments of the present application further provide a display apparatus including any of the above display panels. Since the display apparatus according to the embodiments of the present application includes any of the above display panels, the display apparatus according to the embodiments of the present application has the beneficial effects of any of the above display panels, which is not repeated herein.

The display apparatus according to the embodiments of the present application includes, but is not limited to, a mobile phone, a personal digital assistant (PDA), a tablet computer, an e-book, a television, an entrance guard, a smart fixed-line phone, a console and other devices with display function.

Although the present application has been described with reference to the preferred embodiments, various modifications can be made thereto and components thereof can be replaced with their equivalents without departing from the scope of the present application. In particular, various technical features described in various embodiments can be combined in any manner as long as there is no structural conflict. The present application is not limited to the specific embodiments described herein, and includes all technical solutions that fall within the scope of the claims.

What is claimed is:

1. A display panel, comprising a display region and a non-display region at least partially surrounding the display region, wherein the display panel comprises:
a base plate;
a wiring layer located on a side of the base plate, wherein the wiring layer comprises a metal layer located in the display region and a signal line layer located in the non-display region;
a light-emitting layer located on a side of the wiring layer away from the base plate, wherein the light-emitting layer comprises a plurality of light-emitting units; and
an isolation structure located on a side of the wiring layer away from the base plate, wherein the isolation structure is provided with an isolation opening configured to accommodate the light-emitting unit;
wherein at least a part of a side of the signal line layer away from the base plate is provided with a protection portion.

2. The display panel according to claim 1, wherein the signal line layer comprises a first surface located on a side of the signal line layer away from the base plate and a second surface connected to two sides of the first surface and extending toward the base plate, and the protection portion covers the first surface and the second surface.

3. The display panel according to claim 1, wherein the signal line layer and the metal layer are provided on a same layer, and at least some of materials of the signal line layer and the metal layer are the same.

4. The display panel according to claim 1, wherein the isolation structure is electrically connected to the signal line layer, the metal layer comprises a conductive connection portion, the base plate comprises a driving circuit, the display panel further comprises a first electrode located between the light-emitting layer and the base plate, the first electrode is located on a side of the conductive connection portion away from the driving circuit, and the first electrode and the driving circuit are connected through the conductive connection portion.

5. The display panel according to claim 1, wherein the display panel further comprises a pixel definition layer provided on the base plate, the pixel definition layer comprises a pixel definition portion and a pixel opening defined by the pixel definition portion, the pixel opening and the isolation opening are connected to accommodate the light-emitting unit, an orthographic projection of an inner wall of each of pixel openings on the base plate is located within an orthographic projection of an inner wall of a corresponding isolation opening on the base plate, and at least a part of the protection portion and the pixel definition portion are made of a same material.

6. The display panel according to claim 5, wherein the isolation structure is provided on a side of the pixel definition portion away from the base plate, or the pixel definition portion is provided with an accommodation groove, and the isolation structure is provided in the accommodation groove.

7. The display panel according to claim 1, wherein a material of the protection portion comprises an inorganic material.

8. The display panel according to claim 5, wherein the pixel definition portion is provided with a via, and the signal line layer is electrically connected to the isolation structure through the via.

9. The display panel according to claim 5, wherein the base plate further comprises a planarization layer, and the protection portion comprises a first sub-layer and a second sub-layer stacked along a thickness direction of the base plate, the first sub-layer and the planarization layer are made of a same material, and the second sub-layer and the pixel definition portion are made of a same material.

10. The display panel according to claim 1, wherein the isolation structure comprises a first isolation portion and a second isolation portion located on a side of the first isolation portion away from the base plate, an orthographic projection of the first isolation portion on the base plate is located within an orthographic projection of the second isolation portion on the base plate;
wherein the display panel further comprises a conductive portion located in the non-display region, the conductive portion is located on a side of the protection portion away from the signal line layer, and the conductive portion and the first isolation portion are made of a same material.

11. The display panel according to claim 10, wherein the material of the conductive portion comprises molybdenum or aluminum.

12. The display panel according to claim 10, wherein the isolation structure further comprises a third isolation portion, the first isolation portion is located between the third isolation portion and the second isolation portion, and the conductive portion and the third isolation portion are made of a same material.

13. A method for manufacturing a display panel, comprising:
forming a wiring layer on a side of a base plate, wherein the wiring layer comprises a metal layer located in a display region and a signal line layer located in a non-display region;
forming a protection material layer on a side of the signal line layer away from the base plate, and performing a patterning treatment on the protection material layer to form a protection portion located on the side of the signal line layer away from the base plate;
forming an isolation structure on a side of the wiring layer away from the base plate, wherein the isolation structure is provided with an isolation opening configured to accommodate a light-emitting unit; and
forming the light-emitting unit within the isolation opening.

14. The method for manufacturing the display panel according to claim 13, wherein in the step of forming the protection material layer on the side of the signal line layer away from the base plate, and performing the patterning treatment on the protection material layer to form the protection portion located on the side of the signal line layer away from the base plate: performing the patterning treatment on the protection material layer further forms a pixel definition portion and a pixel opening, the pixel opening and the isolation opening are connected to accommodate the light-emitting unit, an orthographic projection of an inner wall of each of pixel openings on the base plate is located within an orthographic projection of an inner wall of a corresponding isolation opening on the base plate, the pixel opening is configured to accommodate the light-emitting unit, and at least a part of the protection portion and the pixel definition portion are made of a same material.

15. A display apparatus, comprising the display panel according to claim 1.
